(19) United States
(12) Patent Application Publication
(10) Pub. No.: US 2006/0094131 A1
(43) Pub. Date: May 4, 2006

(54) System and method for critical dimension control in semiconductor manufacturing

(75) Inventors: Yu-Hsi Wang, Hsinchu City (TW); Hua-Tai Lin, Yung-Kang City (TW); Chih-Ming Ke, Hsinchu City (TW); Shih-Che Wang, Hsinchu City (TW)

Correspondence Address: HAYNES AND BOONE, LLP, 901 MAIN STREET, SUITE 3100, DALLAS, TX, 75202, US

(73) Assignee: Taiwan Semiconductor Manufacturing Company, Ltd., Hsin-Chu (TW)

(21) Appl. No.: 10/979,515

(22) Filed: Nov. 2, 2004

(51) Int. Cl. H01L 21/66

(52) U.S. Cl. 438/14; 438/16; 356/625

(57) ABSTRACT

Provided are a system and method for modifying a fabrication process based on inline measurement information during manufacture of a semiconductor device. In one example, the method includes exposing a photoresist layer on the device, performing post-exposure baking on the photoresist layer, and obtaining at least one critical dimension (CD) measurement of the device. A determination may be made as to whether the CD measurement indicates that the exposure and/or baking step achieved a predefined result. If not, the device may be subjected to additional exposure or baking.

### CROSS-REFERENCE

This application is related to U.S. patent application Ser. No. ______ (Attorney Docket No. 24061.161, filed on (not yet known), and entitled “PROCESS CONTROLLER FOR SEMICONDUCTOR MANUFACTURING.”

### BACKGROUND

With the advancement of semiconductor manufacturing techniques, current semiconductor fabrication design rules allow ultra large scale integration (ULSI) devices to possess submicron features, increased transistor and circuit speeds, and improved reliability. To ensure that devices forming a circuit are properly sized (e.g., they do not improperly overlap or interact with one another), design rules are used that define parameters, such as the tolerances between devices and interconnecting lines, and the widths of such lines. A design rule limitation, also known as a critical dimension (CD), may define a minimum width of a line or a minimum space between two lines permitted in the fabrication of the devices for a given technology (e.g., 90 nm). CD errors in a device or between devices may arise from any number of sources, such as optical (e.g., lens field curvature or lens aberration in a photolithography system), mechanical, or chemical (e.g., thickness non-uniformity of resist coating and anti-reflection coating (ARC)) sources.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 illustrates one embodiment of a method for identifying a potential CD error during a manufacturing process and adjusting the process to compensate for that error.

FIG. 2 illustrates one embodiment of a partial semiconductor device that may be produced using the method of FIG. 1.

FIG. 3 is a graph of exemplary data illustrating a change in the ‘n’ value of a photoresist before and after post-etch baking.

FIG. 4 is a graph of exemplary data illustrating a change in the ‘k’ value of a photoresist before and after post-etch baking.

FIG. 5 illustrates another embodiment of a method for identifying a potential CD error during a manufacturing process and adjusting the process to compensate for that error.

FIG. 6 illustrates an exemplary system within which the methods of FIG. 1 and/or FIG. 5 may be implemented.

FIG. 7 illustrates a more detailed view of one possible component of the system of FIG. 6.

### DETAILED DESCRIPTION

The present disclosure relates generally to the field of semiconductor manufacturing, and more particularly, to the field of controlling critical dimensions of features formed on semiconductor wafers.

It is understood, however, that the following disclosure provides many different embodiments or examples. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

Lithography systems, which facilitate the projection of patterns onto wafers, may cause CD errors by supplying an incorrect energy amount (e.g., the radiation used for exposure) or unsuitable baking conditions. Accordingly, among other things, it is desirable to provide adequate control of the energy dose and baking conditions to ensure that the CD of a device being fabricated complies with predefined specifications.

Currently, to identify CD errors, CD measurements are generally conducted by destructive methods such as cross-section Scanning Electron Microscope (SEM) or Transmission Electron Microscope (TEM). Such offline approaches introduce limitations into the production cycle time and increase wafer production costs. Additionally, the onset of 300 mm wafer production exacerbates such problems due to higher fabrication costs, increased sampling rate requirements, and the need for integrated metrology on process tools to provide on-tool process control. Therefore, for those reasons and other reasons that will become apparent upon reading the following description, it is desirable to provide an improved system and method of lithography, so that CD measurement and corresponding adjustments may be accomplished inline on a wafer-by-wafer basis instead of a lot-to-lot basis.

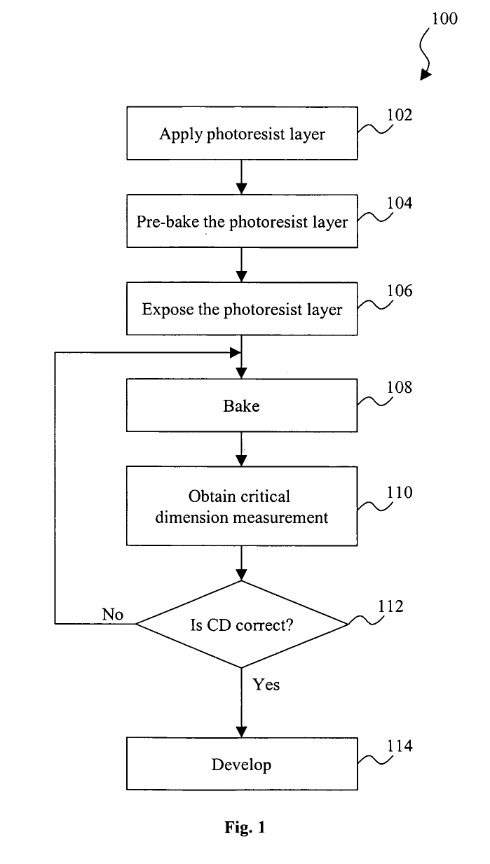

Referring to FIG. 1, in one embodiment, an exemplary method 100 may be used to determine whether a CD measurement is correct and, if it is not, to take corrective steps. The method 100 may be executed inline between or during various semiconductor fabrication steps (e.g., photoresist deposition, exposure, and baking) using, for example, a photolithography tool that has integrated processing and inspection capabilities. For example, the method 100 may be executed with systems such as TEL iODP1 (integrated Optical Digital Profilometry), which is integrated into TEL's Clean Track ACT and Lithius platforms (both from Tokyo Electron America of Austin, Tex.), and ProCell cluster platform (from Silicon Valley Group, Inc., of New York).

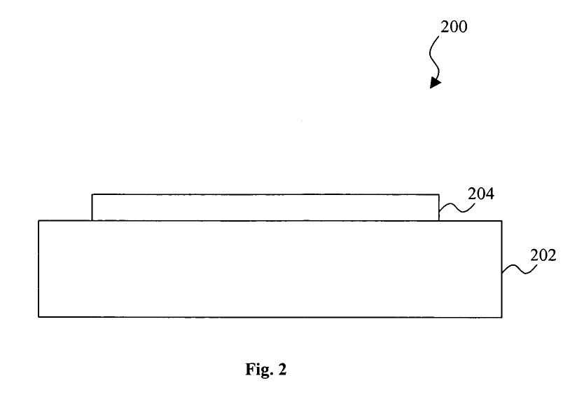

In step 102 of FIG. 1 and with additional reference to FIG. 2, a layer of photoresist 204 is deposited on a wafer 202, which is part of a device 200 that is being fabricated. It is understood that additional layers and structures (e.g., vias, gate structures, etc.) may be present on the wafer 204, but are not shown for purposes of clarity. In step 104, after deposition of the photoresist, the wafer may undergo a pre-bake process. In step 106, the photoresist is exposed using techniques known in the art and, in step 108, the wafer 204 undergoes a post-exposure baking (PEB) process.

In step 110, one or more CD measurements are obtained. The measurements may be obtained using a commercially available system based on a technology such as Optical Digital Profilometry (ODP). As is known, ODP (such as has been developed by Timbre Technologies Inc.) is an optical, nondestructive, inline measurement technique utilizing Maxwell's principles to generate digital cross-sectional representations of integrated circuit features.

In the present embodiment, ODP employs a light source to extract precise CD information from a periodic grating structure on the semiconductor device 200. As the light is reflected from the multiple patterned and unpatterned layers of the partial semiconductor device 200, it is gathered by an optical detector and analyzed by the ODP. A Timbre Profiler Application Server (PAS), paired with a spectroscopic ellipsometer, utilizes the spectroscopic single angle approach coupled with ellipsometry to extract detailed CD information of the partial semiconductor device 200 using both intensity (tan y) and phase (cos Δ) information in the reflected light. Thereafter, using the intensity (tan y) and phase (cos Δ) information, the PAS search engine quickly searches a pre-generated library database containing numerous spectrum parameters and their corresponding CD parameters. After a relatively short period of time (e.g., few seconds), the corresponding thickness, refractive index, and/or extinction coefficient (parameters for CD measurement) of the partial semiconductor device 200 may be obtained. In addition, for future reference, the collected intensity (tan y) and phase (cos Δ) information may also be added to the library database.

In step 112, a determination is made as to whether the PEB of step 108 achieved a desired result. For example, the CD measurement may be used to determine if the resulting wafer is out of spec. If the CD is not correct, the method 100 returns to step 108 and performs an additional baking process on the wafer 202. It is understood that this additional baking process may take place in the same oven as the original step 108, or may take place in another oven. The steps 108-112 may be repeated in real time until it is determined in step 112 that the CD measurements fall within a desired range. In some embodiments, step 110 and/or step 112 may be performed simultaneously with step 108 and the original baking process may be continued (rather than using an additional baking step). In other embodiments, the original wafer 202 may not undergo a further baking process, but the method 100 may be used to adjust baking parameters (e.g., duration and/or temperature) of the PEB process based on the CD measurements for following wafers. If the CD measurements are correct (e.g., fall within a predefined range), then the method continues to step 114, where the wafer is developed. Accordingly, the method 100 enables the processing parameters of the wafer (or lot) to be modified in-line during processing.

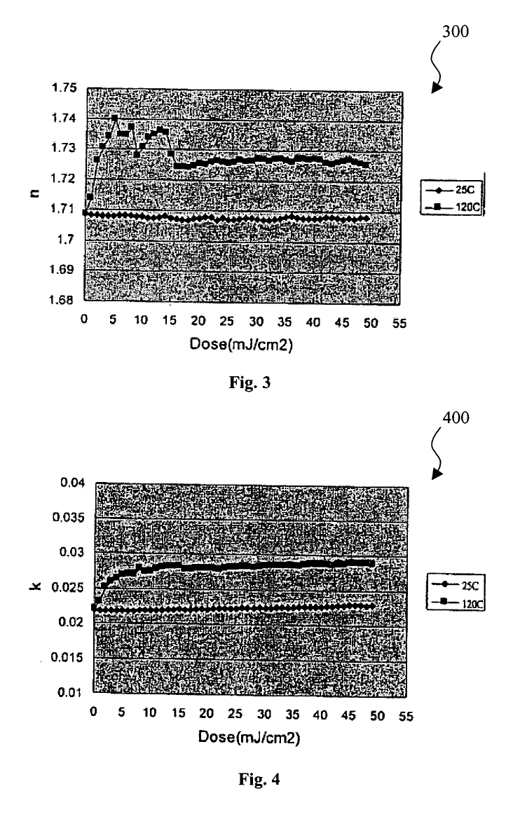

Referring now to FIGS. 3 and 4, graphs 300 and 400 illustrate a change in the ‘n’ value (where ‘n’ is the refractive index) and ‘k’ value (where ‘k’ is the extinction coefficient), respectively, of a photoresist before and after post-etch baking. Generally, the values of ‘n’ and ‘k’ generally exhibit little or no change after exposure. However, as illustrated by the data values representing 25° C. or 115° C., the values of ‘n’ and ‘k’ will change after the PEB process due to the decomposition of the photoresist during baking. Accordingly, these values may be used as parameters to monitor the wafer during and/or after a baking process.

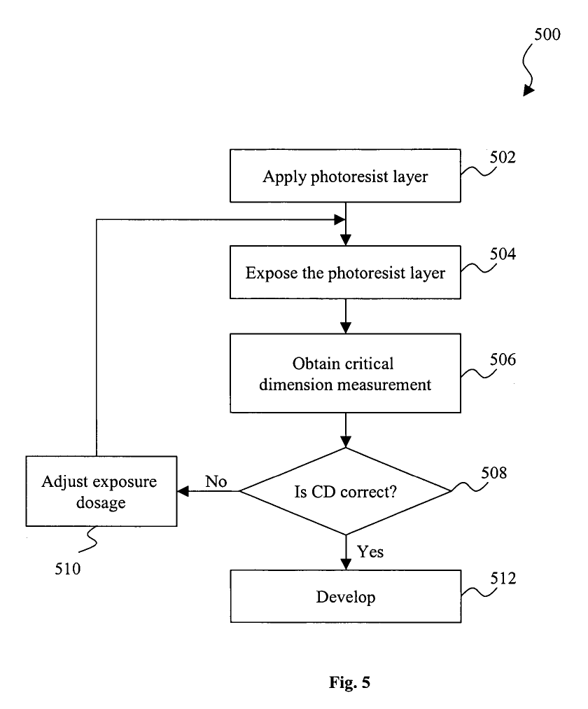

Referring to FIG. 5, in another embodiment, an exemplary method 500 may be used to determine whether a CD measurement is correct and, if it is not, to take corrective steps. As with the method 100 of FIG. 1, the method 500 may be executed inline between or during various semiconductor fabrication steps (e.g., photoresist deposition, exposure, and baking) using, for example, a photolithography tool that has integrated processing and inspection capabilities. Although not shown in the present example, it is understood that the method 500 may include similar baking steps to those of FIG. 1.

In step 502 of FIG. 5, a layer of photoresist is deposited on a wafer (e.g., the wafer 202 of FIG. 2) and, in step 504, the layer of photoresist is exposed. In step 506, one or more CD measurements are obtained. The measurements may be obtained as previously described with respect to the method 100 of FIG. 1. In step 508, a determination is made as to whether the exposure of step 504 achieved a desired result. For example, the CD measurement may be used to determine if the resulting wafer is out of spec. If the CD is not correct, the method 500 adjusts the exposure dosage in step 510 (e.g., by modifying the duration, intensity, etc.) and returns to step 504. The steps 504-508 may be repeated in real time until it is determined step 508 that the CD measurements fall within a desired predefined range. In some embodiments, step 506 and/or step 508 may be performed simultaneously with step 504 and the original exposure process may be continued (rather than using an additional exposure step). In other embodiments, the original wafer may not undergo further exposure, but the method 500 may be used to adjust the exposure dosage for following wafers. If the CD measurements are correct (e.g., fall within a predefined range), then the method continues to step 512, where the wafer is developed.

It is understood that the methods 100 and 500 may reside on a single system and may be run separately (e.g., only one of the methods may be run on a single wafer), sequentially (e.g., the methods may be run in sequence on a single wafer), or simultaneously. For example, the method 500 may be used to ensure that the CD measurements are within a certain range prior to the PEB process, while the method 100 may be used to ensure that the CD measurements are within a certain range following the PEB process. Accordingly, although shown separately, the methods 100 and 500 may be integrated into a single method for real time CD control. Furthermore, in some embodiments, a determination may be made as to whether to use the additional baking of the method 100 or the additional exposure of the method 500 based on the CD measurements. For example, analysis of the CD measurements may reveal that it is more efficient (based on time, energy requirements, overall process flow in the fabrication facility, etc.) to use additional baking or additional exposure.

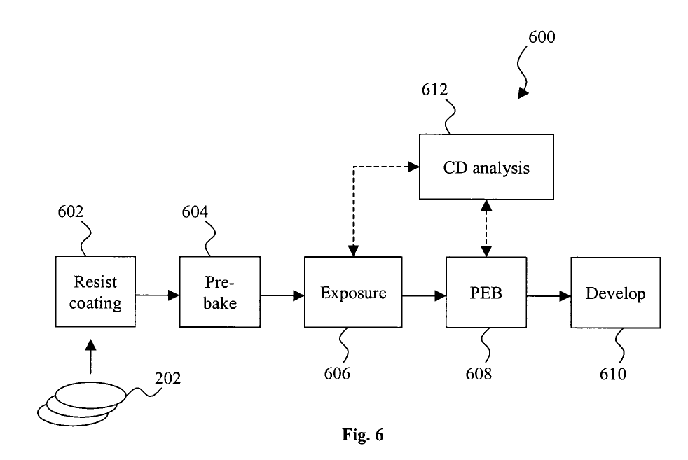

Referring now to FIG. 6, basic components of an exemplary semiconductor processing system are illustrated. The various components may be separate pieces of processing equipment or various components may be combined into a single piece of processing equipment. A process flow through the components for wafer or lot 202 includes resist coating 602, pre-baking 604, exposure 606, post-exposure baking 608, and developing 610. In addition, as previously described, an inline CD analysis tool 612 is used to obtain CD information about a wafer prior to a developing step and use that information to provide feedback to the system 600. The feedback may be used to make real-time adjustments that affect the processing of the same wafer/lot from which the information was obtained.

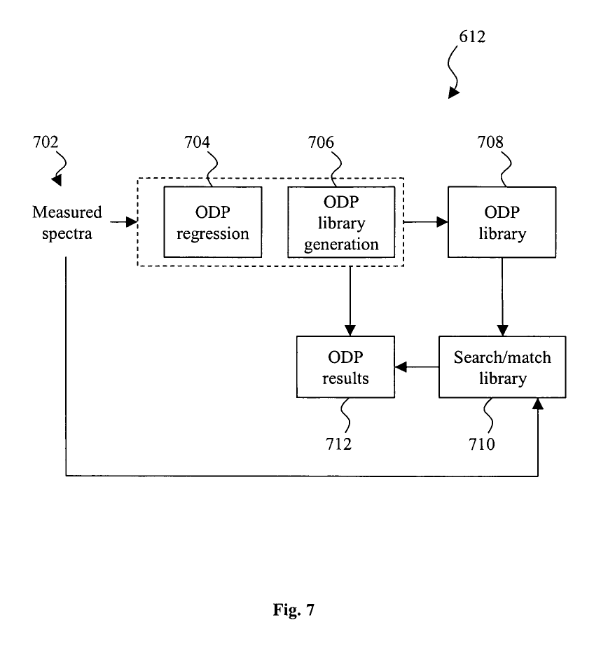

With additional reference to FIG. 7, an exemplary CD analysis tool 612, such as TEL's previously identified iODP1, is illustrated in greater detail. The tool 612 receives spectral analysis information 702. Using this information, the tool 612 may run a regression profile 704 as well as perform library generation tasks 706. The regression information may then be entered with other ODP library information 708 into a search and match library 710 to identify and categorize results 712 using a tool such as Timbre's Profiler Application Server (PAS). The results 712 may be used to modify the processing parameters or the results themselves may be altered to include information directing such modifications.

While the preceding description shows and describes one or more embodiments, it will be understood by those skilled in the art that various changes in form and detail may be made therein without departing from the spirit and scope of the present disclosure. For example, various steps of the described methods may be executed in a different order or executed sequentially, combined, further divided, replaced with alternate steps, or removed entirely. In addition, various functions illustrated in the methods or described elsewhere in the disclosure may be combined to provide additional and/or alternate functions. Therefore, the claims should be interpreted in a broad manner, consistent with the present disclosure.

What is claimed is:

1. A method for modifying a fabrication process based on inline measurement information during manufacture of a semiconductor device, the method comprising:
performing post-exposure baking on a photoresist layer on the semiconductor device;
obtaining at least one critical dimension (CD) measurement of the semiconductor device;
determining whether the CD measurement indicates that the baking step achieved a predefined result; and
performing additional baking of the photoresist layer if the predefined result was not achieved.

2. The method of claim 1 further comprising adjusting at least one parameter of the baking step based on the CD measurement.

3. The method of claim 2 wherein the additional baking is performed using the adjusted parameter without removing the semiconductor device from equipment used for the post-exposure baking of the photoresist layer.

4. The method of claim 2 wherein the parameter is adjusted in real time.

5. The method of claim 1 wherein determining whether the CD measurement indicates that the baking step achieved a predefined result includes examining at least one spectral indicator obtained during the CD measurement.

6. The method of claim 5 wherein determining whether the CD measurement indicates that the baking step achieved a predefined result includes using a refractive index and an extinction coefficient of the photoresist.

7. The method of claim 5 wherein examining at least one spectral indicator includes utilizing spectral intensity (tan ψ) and phase (cos Δ) information.

8. The method of claim 1 further comprising:
exposing the photoresist;
determining whether the CD measurement indicates that the exposure dosage was correct;
adjusting the exposure dosage based on the CD measurement if the exposure dosage is not correct; and
performing additional exposure of the photoresist layer using the adjusted exposure dosage if the exposure dosage was not correct.

9. A method for modifying a fabrication process based on inline measurement information during manufacture of a semiconductor device, the method comprising:
exposing a photoresist layer on the semiconductor device using an exposure dosage;
obtaining at least one critical dimension (CD) measurement of the semiconductor device;
determining whether the CD measurement indicates that the exposure dosage is correct; and
performing additional exposure of the photoresist layer if the exposure dosage was not correct.

10. The method of claim 9 further comprising adjusting the exposure dosage based on the CD measurement, wherein the additional exposure of the photoresist layer is performed using the adjusted exposure dosage.

11. The method of claim 10 wherein the parameter is adjusted in real time.

12. The method of claim 9 wherein the additional exposure is performed without removing the semiconductor device from equipment used for the original exposure step.

13. The method of claim 9 wherein determining whether the CD measurement indicates that the exposure dosage was correct includes examining at least one spectral indicator obtained during the CD measurement.

14. The method of claim 13 wherein examining at least one spectral indicator includes utilizing spectral intensity (tan ψ) and phase (cos Δ) information.

15. A method for correcting a fabrication parameter based on inline measurement information during manufacture of a semiconductor device, the method comprising:
exposing a photoresist layer on the semiconductor device;
baking the photoresist layer on the semiconductor device;
obtaining at least one critical dimension (CD) measurement of the semiconductor device;
adjusting the parameter based on the CD measurement; and
performing at least one of an additional exposing step or an additional baking step on the semiconductor device using the adjusted parameter.

16. The method of claim 15 further comprising:
determining whether the CD measurement falls within a predefined range; and
adjusting the parameter only if the CD measurement does not fall within the predefined range.

17. The method of claim 15 further comprising determining whether the additional exposing step or the additional baking step is more efficient and selecting the more efficient step.

18. A system for correcting a fabrication parameter based on inline measurement information during manufacture of a semiconductor device, the method comprising:
means for exposing a photoresist layer on the semiconductor device;
means for baking the photoresist layer on the semiconductor device;
means for obtaining at least one critical dimension (CD) measurement of the semiconductor device;
means for adjusting the fabrication parameter based on the CD measurement; and
means for performing at least one of an additional exposing step or an additional baking step on the semiconductor device using the adjusted parameter.

19. The system of claim 18 further comprising:
means for determining whether the CD measurement falls within a predefined range; and
means for adjusting the parameter only if the CD measurement does not fall within the predefined range.

20. The system of claim 18 further comprising means for determining whether the additional exposing step or the additional baking step is more efficient and selecting the more efficient step.

21. The system of claim 18 wherein the means for obtaining at least one CD measurement includes the use of an optical digital profilometry tool.
